(19) United States
(12) Patent Application Publication
(10) Pub. No.: US 2024/0405188 A1
(43) Pub. Date: Dec. 5, 2024

(54) METHOD OF ADJUSTING TEMPERATURE OF ELECTRONIC APPARATUS AND ELECTRONIC APPARATUS

(71) Applicant: Japan Display Inc., Tokyo (JP)

(72) Inventors: Daiki ISONO, Tokyo (JP); Kazuyuki YAMADA, Tokyo (JP); Keisuke ASADA, Tokyo (JP); Kenichi TAKEMASA, Tokyo (JP)

(21) Appl. No.: 18/672,388

(22) Filed: May 23, 2024

(30) Foreign Application Priority Data
May 29, 2023 (JP) 2023-088005

(51) Int. Cl. H01L 33/64; G09G 3/32; H01L 25/075

(52) U.S. Cl. CPC H01L 33/648; G09G 3/32; H01L 25/0753; G09G 2330/045

(57) ABSTRACT

A technique for more appropriately adjusting a temperature of an electronic apparatus is provided. Temperatures of a panel substrate are detected in a plurality of measurement regions set in the panel substrate, and temperatures in a plurality of adjustment regions set in the panel substrate are individually adjusted in accordance with the temperatures of the panel substrate detected in the plurality of measurement regions.

### CROSS-REFERENCE TO RELATED APPLICATION

The present application claims priority to Japanese Patent Application No. 2023-88005 filed on May 29, 2023, the disclosure of which is incorporated herein by reference.

### TECHNICAL FIELD OF THE INVENTION

The present disclosure relates to a method of adjusting a temperature of an electronic apparatus and relates to an electronic apparatus.

### BACKGROUND OF THE INVENTION

Some electronic apparatuses each including an element mounted on a panel substrate perform, for example, temperature adjustment such as heat radiation or cooling of the element as measures against heat produced in the element. Japanese Patent Application Laid-open Publication No. 2016-119362 (Patent Document 1) discloses a configuration of an organic EL display apparatus serving as the electronic apparatus in which a heat radiator sheet including a thin metal wire is stacked on a transparent organic EL panel in order to radiate heat from the transparent organic EL panel on which a plurality of transparent organic EL elements are mounted. Japanese Patent Application Laid-open Publication No. 2003-124671 (Patent Document 2) discloses a configuration in which a personal computer as the electronic apparatus includes a cooling system configured to cool a CPU serving as the element by using a liquid medium circulated by a pump.

Japanese Patent Application Laid-open Publication No. 2020-12972 (Patent Document 3) describes a configuration accelerating heat radiation from an inorganic light emitting element since a first surface of a substrate of a display apparatus serving as the electronic apparatus includes the inorganic light emitting element (microLED) while a second surface of the substrate of the same includes a heat radiating section such that a cathode electrode of the inorganic light emitting element and the heat radiating section are connected by a heat transferring section.

### SUMMARY OF THE INVENTION

An objective of the present disclosure is to provide a technique for more appropriately performing temperature adjustment of an electronic apparatus.

A method of adjusting a temperature of an electronic apparatus according to one aspect of the present disclosure is a method of adjusting a temperature of an electronic apparatus including a panel substrate on which a plurality of elements are mounted, and the method includes: a first step of detecting temperatures of the panel substrate in a plurality of measurement regions set on the panel substrate; and a second step of individually adjusting temperatures of a plurality of adjustment regions set on the panel substrate in accordance with the temperatures of the panel substrate detected in the plurality of measurement regions.

An electronic apparatus according to one aspect of the present disclosure is an electronic apparatus including a panel substrate on which a plurality of elements are mounted, and the electronic apparatus includes: a plurality of temperature detectors provided in a plurality of measurement regions set on the panel substrate and configured to detect temperatures of the panel substrate; a temperature adjuster including a plurality of temperature adjusting units corresponding to a plurality of adjustment regions set on the panel substrate and configured to adjust the temperatures of the panel substrate; and a controller configured to control an operation of the temperature adjuster. The controller individually controls operations of the temperature adjusting units in accordance with the temperatures of the panel substrate in the plurality of measurement regions detected by the plurality of temperature detectors.

### BRIEF DESCRIPTIONS OF THE DRAWINGS

FIG. 1 is a plan view showing an exemplary configuration of a display panel of a microLED display apparatus serving as an electronic apparatus.

FIG. 2 is a circuit diagram showing an exemplary configuration of a circuit around a pixel of FIG. 1.

FIG. 3 is a transparent enlarged plan view showing an example of a peripheral structure of an LED element arranged in each of a plurality of pixels of the display panel of FIG. 1.

FIG. 4 is an enlarged cross-sectional view taken along a line A-A of FIG. 3.

FIG. 5 is a diagram schematically showing an entire configuration of a display apparatus according to one embodiment.

FIG. 6 is a diagram schematically showing a configuration of a temperature adjuster of the display apparatus according to one embodiment.

FIG. 7 is a cross-sectional view of a cooling member taken along a line B-B of FIG. 6.

FIG. 8 is an enlarged diagram schematically showing a configuration of a display panel of the display apparatus according to one embodiment.

FIG. 9 is a diagram showing a modification example of an arrangement of temperature sensors.

FIG. 10 is a diagram showing a modification example of an arrangement of the temperature sensors.

FIG. 11 is a flowchart for explaining an example of a method of adjusting a temperature of the display apparatus according to one embodiment.

### DESCRIPTIONS OF THE PREFERRED EMBODIMENTS

The following is explanation for each embodiment of the present invention with reference to drawings. Note that only one example is disclosed. Appropriate modification with keeping the idea of the present invention which can be anticipated by those who are skilled in the art is obviously within the scope of the present invention. Also, in order to make the explanation clear, a width, a thickness, a shape, and others of each portion in the drawings are schematically illustrated more than those in an actual aspect in some cases. However, the illustration is only an example, and does not limit the interpretation of the present invention. In the present specification and each drawing, similar elements to those described earlier for the already-described drawings are denoted with the same or similar reference characters, and detailed explanation for them is appropriately omitted in some cases.

A micro light emitting diode (referred to as microLED below) display apparatus on which a plurality of microLEDs that are self-emitting elements are mounted will be exemplified and explained below as an example of an electronic apparatus on which a plurality of elements are mounted. In the following explanation, note that the microLED display apparatus may be simply referred to as display apparatus. The electronic apparatuses may include not only the display apparatus but also, for example, electronic equipment in which the display apparatus is embedded.

### <Exemplary Basic Configuration of Display Panel>

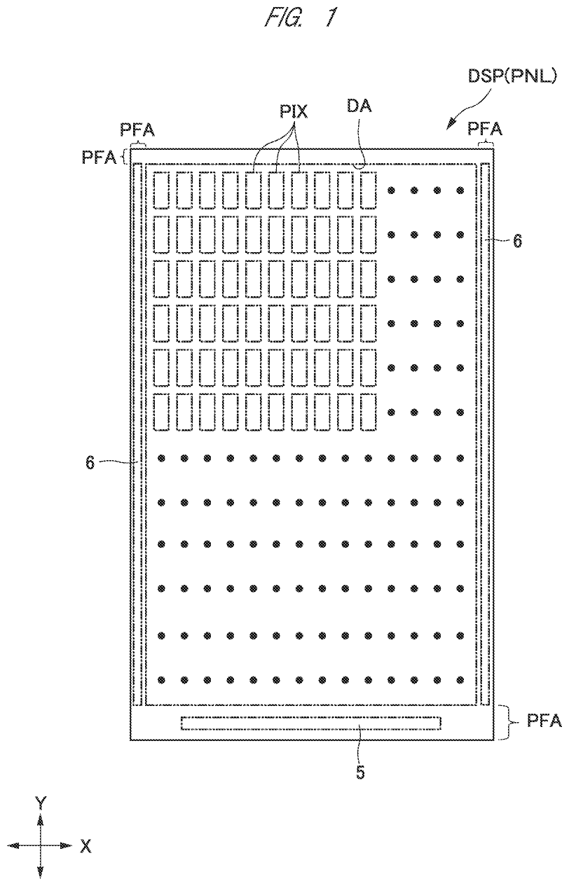

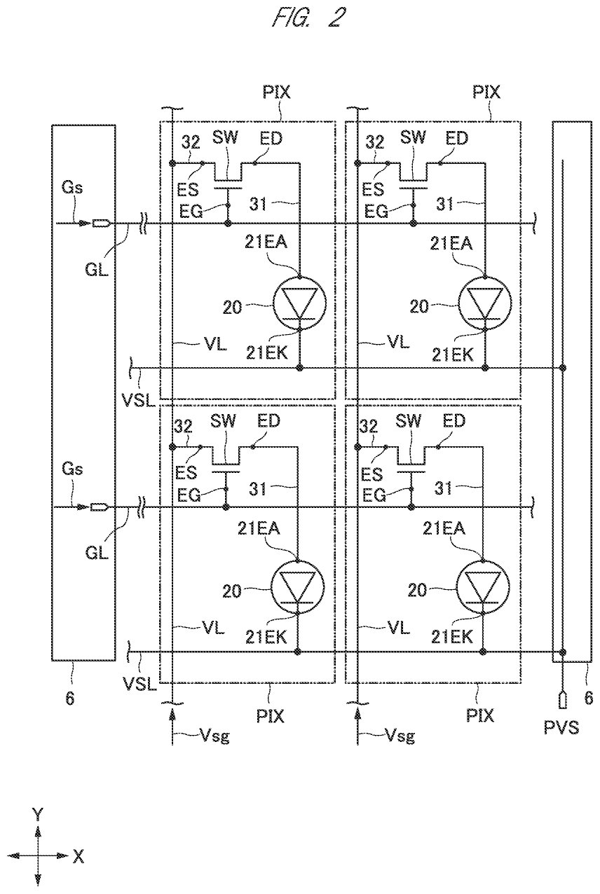

First, an exemplary basic configuration of a display panel of the microLED display apparatus will be explained. FIG. 1 is a plan view showing an exemplary configuration of the display panel. In FIG. 1, each of a boundary between a display region DA and a peripheral region PFA, a control circuit 5, a drive circuit 6 and a plurality of pixels PIX is illustrated with a dashed double-dotted line. FIG. 2 is a circuit diagram showing an exemplary configuration of a circuit around the pixel of FIG. 1.

As shown in FIG. 1, a display panel PNL of the microLED display apparatus DSP includes the display region DA, the peripheral region PFA having a frame form surrounding the display region DA, and a plurality of pixels PIX arranged in a matrix pattern inside the display region DA. The display panel PNL includes: a panel substrate 10 having a quadrangular plane shape; the control circuit 5 formed on the panel substrate 10; and the drive circuit 6 formed on the panel substrate 10. The panel substrate 10 is made of glass or resin.

The control circuit 5 is a control circuit controlling driving of a display function of the display panel PNL. The control circuit 5 is, for example, a driver integrated circuit (IC) mounted on the panel substrate 10. In the example of FIG. 1, the control circuit 5 is arranged along one short side of four sides of the panel substrate 10, that is, along an X direction in the drawing. In the following explanation, note that a short side direction of the panel substrate 10 may be referred to as X direction, a long side direction of the panel substrate 10 may be referred to as Y direction, and a thickness direction of the panel substrate 10 may be referred to as Z direction.

In this example, the control circuit 5 includes a signal-line drive circuit configured to drive a wiring (video signal wiring) VL (see FIG. 2) connected to the plurality of pixels PIX. The position and configuration of the control circuit 5 is not limited to the example of FIG. 1, and include various modification examples. For example, in FIG. 1, a wiring substrate such as a flexible circuit board may be connected to a position illustrated as the control circuit 5, and the driver IC may be mounted on this wiring substrate. Alternatively, for example, the signal-line drive circuit configured to drive the wiring VL may be formed separately from the control circuit 5.

The drive circuit 6 includes a circuit configured to drive a scan signal line GL (see FIG. 2) of the plurality of pixels PIX. The drive circuit 6 includes a circuit configured to supply a reference potential to the LED element mounted on each of the plurality of pixels PIX. The drive circuit 6 drives the plurality of scan signal lines GL on the basis of a control signal output from the control circuit 5. In the example of FIG. 1, the drive circuit 6 is arranged along each of two long sides of the four sides of the panel substrate 10. The position and exemplary configuration of the drive circuit 6 are not limited to the example of FIG. 1, and include various modification examples. For example, in FIG. 1, a wiring substrate such as a flexible circuit board may be connected to a position illustrated as the control circuit 5, and the drive circuit 6 may be mounted on the wiring substrate.

Next, an exemplary circuit configuration of the pixels PIX will be explained with reference to FIG. 2. Note that FIG. 2 shows four pixels PIX, and each of the plurality of pixels PIX shown in FIG. 1 includes the same circuit as those of the pixels PIX shown in FIG. 2. A circuit including a switching element SW and an LED element 20 of the pixel PIX may be referred to as a pixel circuit below. The pixel circuit is a circuit of a voltage signal system for controlling a light emission state of the LED element 20 in response to a video signal Vsg supplied from the control circuit 5 (see FIG. 1).

As shown in FIG. 2, each pixel PIX includes the LED element 20 serving as the self-emitting element. The LED element 20 includes an anode electrode 21EA and a cathode electrode 21EK. The cathode electrode 21EK of the LED element 20 is connected to a wiring VSL to which a reference potential (fixed potential) PVS is supplied. The anode electrode 21EA of the LED element 20 is electrically connected to a drain electrode ED of the switching element SW through a wiring 31.

Each pixel PIX includes the switching element SW. The switching element SW is a transistor configured to control a connection state (ON/OFF state) between the pixel circuit and the wiring VL in response to a control signal Gs. The switching element SW is, for example, a thin-film transistor. When the switching element SW is in the ON state, the video signal Vsg is input from the wiring VL into the pixel circuit.

The drive circuit 6 includes a shift register circuit, an output buffer circuit, and the like not illustrated. On basis of a horizontal scan start pulse transmitted from the control circuit 5 (see FIG. 1), the drive circuit 6 outputs a pulse and outputs the control signal Gs.

Each of the plurality of scan signal lines GL extends in the X direction. The scan signal line GL is connected to a gate electrode EG of the switching element SW. By the supply of the control signal Gs to the scan signal line GL, the switching element SW is turned ON, and the video signal Vsg is supplied to the LED element 20.

### <Peripheral Configuration of LED Element>

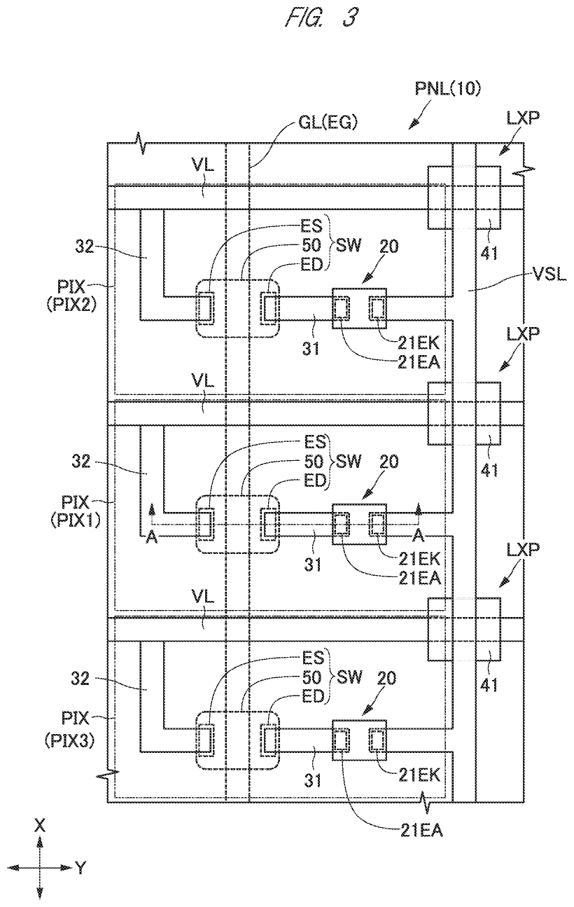

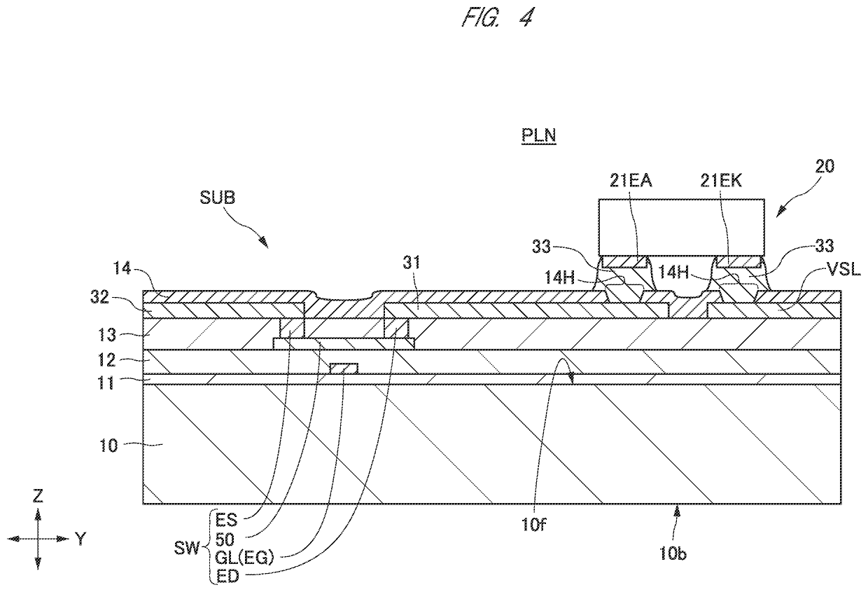

Next, a peripheral configuration of the LED element 20 arranged in each of the plurality of pixels PIX shown in FIG. 1 will be explained. FIG. 3 is a transparent enlarged plan view showing an example of the peripheral configuration of the LED element arranged in each of the plurality of pixels of the display apparatus of FIG. 1. In FIG. 3, an inorganic insulative layer 14 shown in FIG. 4 is omitted. In FIG. 3, each outline of a semiconductor layer, an electrode, and a scan signal line is illustrated with a dotted line. FIG. 4 is an enlarged cross-sectional view taken along a line A-A of FIG. 3.

The display panel PNL includes a plurality of pixels PIX (pixels PIX1, PIX2, and PIX3 in the example of FIG. 3) as shown in FIG. 3. Each of the pixels PIX includes the switching element SW, the LED element (light-emitting element) 20, the wiring 31, and a wiring 32. For example, the LED element 20 configured to emit a visible light of any one of red, green, and blue is mounted on each of the pixels PIX1, PIX2, and PIX3 and the switching element SW configured to drive the LED element 20 is formed therein.

When the visible lights of the respective colors are emitted from the pixels PIX1, PIX2, and PIX3, the output and timings of the visible lights emitted from the LED elements 20 in the pixels PIX1, PIX2, and PIX3 are controlled to enable color display in the display panel PNL. When a plurality of pixels PIX, which emit visible lights of mutually different colors, are combined in this way, a pixel for each color may be referred to as a sub-pixel and a set of sub-pixels may be referred to as a pixel.

The wiring 31 is electrically connected to the drain electrode ED of the switching element SW and the anode electrode 21EA of the LED element 20. The wiring 32 is connected to a source electrode ES of the switching element SW. In the example of FIG. 3, the wiring 32 has a bent structure where one end thereof is connected to the source electrode ES of the switching element SW and the other end thereof is connected to the wiring VL. The scan signal line GL is used as the gate electrode EG of the switching element SW.

The display panel PNL further includes wirings VL and wirings VSL. A wiring VL extends over a plurality of pixels PIX (see FIG. 2) along the Y direction and is electrically connected to the wirings 32. A wiring VSL extends over a plurality of pixels PIX along the X direction crossing with (orthogonal to, in FIG. 3) the Y direction and is electrically connected to the cathode electrodes 21EK of the LED elements 20. A wiring VL and a wiring VSL cross with each other through an insulative layer 41 at a wiring crossing section LXP shown in FIG. 3. The insulative layer 41 is present between the wiring VL and the wiring VSL and thus the wiring VL and the wiring VSL are electrically isolated from each other.

The display panel PNL includes the LED elements 20 and a substrate structure SUB as shown in FIG. 4. The substrate structure SUB includes the panel substrate 10 made of glass or resin and a plurality of insulative layers stacked on the panel substrate 10. The insulative layers of the substrate structure SUB include an inorganic insulative layer 11, an inorganic insulative layer 12, an inorganic insulative layer 13, and the inorganic insulative layer 14 which are stacked on the panel substrate 10. The panel substrate 10 has a surface 10f and a surface 10b opposite to the surface 10f. The inorganic insulative layers 11, 12, 13, and 14 are stacked on the surface 10f of the panel substrate 10.

The switching element SW includes the inorganic insulative layer 12 formed on the panel substrate 10, a semiconductor layer 50 formed on the inorganic insulative layer 12, the drain electrode ED connected to a drain region of the semiconductor layer 50, the source electrode ES connected to a source region of the semiconductor layer 50, and the inorganic insulative layer 13 covering the semiconductor layer 50. The wiring 31 and the wiring 32 are stacked films each including conductor layers made of titanium or a titanium alloy and a conductor layer made of aluminum or an aluminum alloy, for example. The stacked film in which the aluminum layer is sandwiched between the titanium layers is referred to as a TAT stacked film.

The example of FIG. 4 is in a bottom-gate system in which the gate electrode EG is present between the semiconductor layer 50 and the panel substrate 10. In the bottom-gate system, a part of the inorganic insulative layer 12 between the gate electrode EG and the semiconductor layer 50 functions as a gate insulative layer. The inorganic insulative layer 12 also functions as an underlying layer for forming the semiconductor layer 50. The gate electrode EG is not limited to the example of FIG. 4 in its position and may be in a top-gate system, for example.

Materials making the inorganic insulative layers 11, 12, 13, and 14 are not particularly limited, and may be silicon oxide (SiOc), silicon nitride (SiN), or the like, for example. The semiconductor layer 50 is a semiconductor film in which P-type or N-type conductive impurities are doped in a silicon film made of silicon, for example.

The source electrode ES and the drain electrode ED are contact plugs for electric contact with either one of the source region and the drain region of the semiconductor layer 50. A material of the contact plugs may be tungsten or the like, for example. As a modification example of the example of FIG. 4, contact holes for exposing the source region and the drain region of the semiconductor layer 50 may be formed in the inorganic insulative layer 13 and part of the wiring 31 and part of the wiring 32 may be embedded in the contact holes. In this case, the parts of the wiring 31 and the wiring 32, which are embedded in the contact holes, contact with the semiconductor layer 50, and the contact interfaces between the wirings 31, 32 and the semiconductor layer 50 can be regarded as the drain electrode ED and the source electrode ES.

### Exemplary Configuration of Display Apparatus According to One Embodiment

As described above, the LED elements 20 are mounted on the panel substrate 10 (substrate structure SUB) in the display panel PNL in the display apparatus DSP. That is, the display panel PNL includes the panel substrate 10 on which the LED elements 20 are mounted. The LED elements 20 produce heat when emitting a light. Thus, when the LED elements 20 emit a light, the temperature of the panel substrate 10 on which the LED elements 20 are mounted rises. As measures against the rise in temperature of the panel substrate 10 or measures against heat produced in the LED elements 20, a cooling member configured to cool the panel substrate 10, which is fixedly adhered to the panel substrate 10, may be provided.

The cooling member is provided with one system of medium flow channels, for example, and a cooling medium is circulated in the medium flow channels to cool the entire panel substrate 10. In this case, if the panel substrate 10 is relatively small, the entire panel substrate 10 on which the LED elements 20 are mounted can be uniformly cooled.

However, if the panel substrate 10 is relatively large, the entire panel substrate 10 on which the LED elements 20 are mounted is difficult to be uniformly cooled, and temperature differences may be caused in some parts of the panel substrate 10. In this case, if the entire panel substrate 10 is to be cooled to a desired temperature, part of the panel substrate 10 can be supercooled, for example. When the panel substrate 10 is supercooled, condensation is cased in the panel substrate 10 and failures such as lighting failure can be caused due to condensation. To the contrary, when the entire panel substrate 10 is to be cooled without being partially supercooled, part of the panel substrate 10 can be insufficiently cooled.

A temperature adjustment is individually performed in each of a plurality of regions in the panel substrate in the display apparatus according to one embodiment as described below. For example, the display apparatus individually adjusts cooling states of a cooling member in a plurality of adjustment regions preset in the panel substrate.

A method of cooling a display panel, more specifically a method of cooling a panel substrate on which a plurality of LED elements are mounted will be described below as one exemplary method of adjusting a temperature of a display apparatus. A panel substrate on which a plurality of LED elements are mounted will be simply referred to as panel substrate in the following description.

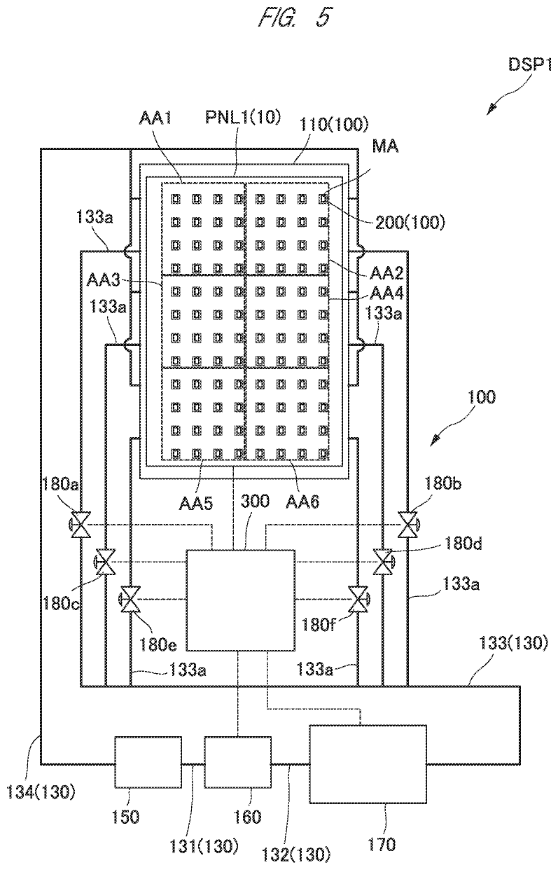

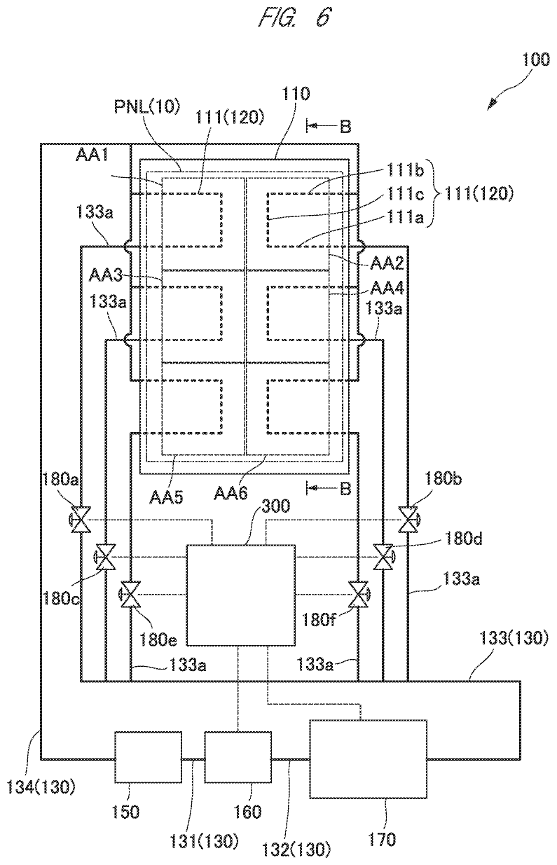

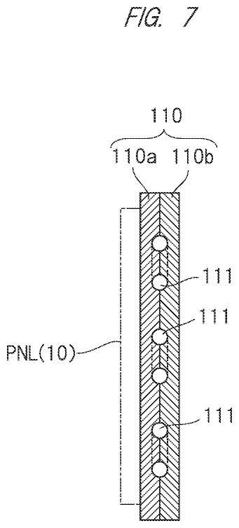

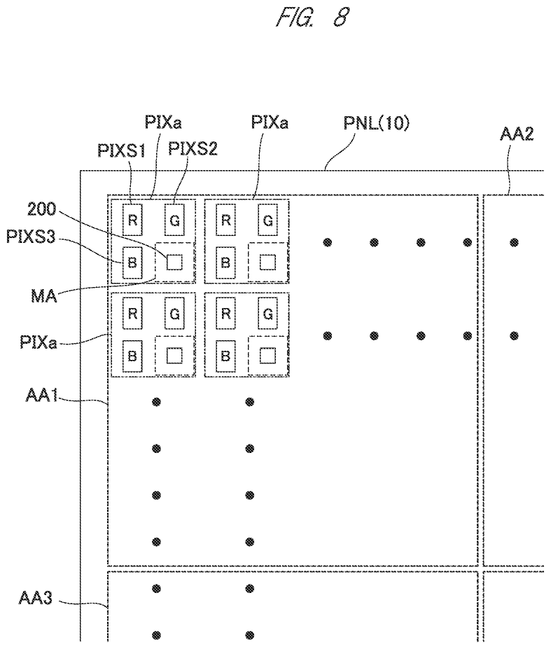

FIG. 5 is a diagram schematically showing an entire configuration of a display apparatus according to one embodiment. FIG. 6 is a diagram schematically showing a configuration of a temperature adjuster in the display apparatus according to one embodiment. FIG. 7 is a cross-sectional view of a cooling member taken along a line B-B of FIG. 6. FIG. 8 is an enlarged diagram schematically showing a configuration of a display panel in the display apparatus according to one embodiment.

As shown in FIGS. 5 and 6, a display apparatus DSP1 according to one embodiment includes a display panel PNL1 including the panel substrate 10 (or the substrate structure SUB) on which a plurality of LED elements 20 are mounted. The display apparatus DSP1 further includes a cooler 100 as an exemplary temperature adjuster configured to adjust a temperature of the panel substrate 10 configuring the display panel PNL1, temperature sensors 200 serving as temperature detectors configure to detect a temperature of the panel substrate 10, and a controller 300 configured to control operations of the cooler 100.

### <Temperature Adjuster>

The cooler 100 serving as an example of the temperature adjuster includes the cooling member 110 connected to the panel substrate 10 configuring the display panel PLN1. The cooler 100 cools the panel substrate 10 and the plurality of LED elements 20 mounted on the panel substrate 10 by using the cooling member 110.

The cooling member 110 is made of a plate-shaped member having a larger quadrangular plane shape than that of the panel substrate 10, and is adhesively fixed to the panel substrate 10 through a heat radiator sheet made of a material having higher heat conductivity than that of the panel substrate 10 although not illustrated. Note that the cooling member 110 may also function as a frame for holding the panel substrate 10.

Inside the cooling member 110, as shown in FIGS. 7 and 8, a plurality of medium flow channels 111 in which a cooling medium serving as an example of a temperature adjusting medium circulates are independently provided. In FIG. 7, each of the medium flow channel 111 provided inside the cooling member 110 is illustrated with a dotted line. The cooling member 110 is made of, for example, plate-shaped first member 110a and second member 110b, and the medium flow channels 111 are formed on a connection surface between the first member 110a and the second member 110b. The cooling member 110 is of course not limited to the above-described configuration.

In this case, a plurality of adjustment regions AA are preset in the panel substrate 10. In the example of FIG. 5, six adjustment regions AA1 to AA6 are set in the panel substrate 10. The plurality of medium flow channels 111 correspond to the plurality of adjustment regions AA, respectively. That is, the cooling member 110 is provided with six independent medium flow channels 111. In other words, the cooler 100 includes a plurality of cooling units (temperature adjusting units) 120 corresponding to the respective adjustment regions AA of the panel substrate 10, and the cooling units 120 include the respective independent medium flow channels 111.

Although described in detail later, the temperature adjustments of the adjustment regions AA of the panel substate 10 are individually performed by appropriate control for circulation states of the cooling medium circulating in the medium flow channels 111. That is, the adjustment region AA is a region where the temperature adjustment is individually performed by the temperature adjuster (cooler) 100.

Each medium flow channel 111 corresponding to each adjustment region AA is made of a predetermined flow channel pattern. For example, as shown in FIG. 6, each medium flow channel 111 is made of an inlet flow channel section 111a and an outlet flow channel section 111b which linearly extend, and a joint flow channel section 111c which extends in a direction crossing the inlet flow channel section 111a and the outlet flow channel section 111b and connects both of them. The flow channel pattern of each medium flow channel 111 is of course not particularly limited to this example. In this example, although the medium flow channels 111 corresponding to the adjustment regions AA are made of the same flow channel pattern, the medium flow channels 111 may be made of different flow channel patterns. Note that a type of the cooling medium to be circulated in the medium flow channels 111 is not particularly limited but may be, for example, coolant, antifreeze solution, or the like.

The cooling member 110 is made of, for example, single member continuously formed over the plurality of adjustment regions AA of the panel substrate 10. However, the present invention is not limited to the configuration. The cooling member 110 may be divided to correspond to each adjustment region AA. That is, the cooling member 110 may be made of a plurality of members each including a medium flow channel 111 corresponding to each adjustment region AA.

The inlet flow channel section 111a and the outlet flow channel section 111b configuring each medium flow channel 111 are connected through a circulation pipe 130. In other words, the cooler 100 is configured such that the cooling medium circulates in each medium flow channel 111 through the circulation pipe 130. The middle of the circulation pipe 130 is provided with a reservoir tank 150, a pump 160, and a cooling device 170.

For example, the reservoir tank 150 is arranged closer to the outlet flow channel section 111b than the pump 160 while the cooling device 170 is arranged closer to the inlet flow channel section 111a than the pump 160. However, the arrangement of the reservoir tank 150, the pump 160, and the cooling device 170 is not particularly limited. The reservoir tank 150, the pump 160, and the cooling device 170 are only needed to be arranged such that the cooling medium is appropriately supplied to each medium flow channel 111 of the cooling member 110.

The reservoir tank 150 is a tank configured to store the cooling medium such as the coolant to be circulated in each medium flow channel 111, and is connected to the pump 160 through a first circulation pipe 131. The pump 160 is connected to the cooling device 170 through a second circulation pipe 132. The pump 160 is directed to cause the cooling medium stored in the reservoir tank 150 to circulate in each medium flow channel 111 and the circulation pipe 130, and its configuration is not particularly limited.

The cooling device 170 cools the cooling medium flowing from the reservoir tank 150 through the second circulation pipe 132. For example, the cooling device 170 is configured to include a Peltier element such that the cooling medium is cooled by the Peltier element. The configuration of the cooling device 170 is of course not particularly limited if being capable of cooling the cooling medium.

The cooling device 170 is connected to the inlet flow channel section 111a of each medium flow channel 111 through a third circulation pipe 133. More specifically, the third circulation pipe 133 is branched at the middle into a plurality of (in this example, six) branch pipes 133a, and each of the branch pipes 133a is connected to the inlet flow channel section 111a of each medium flow channel 111. The branch pipes 133a are provided with respective flowrate regulating valves 180a to 180f each made of, for example, a solenoid valve or the like and configured to adjust a circulation amount of the cooling medium. The output flow channel section 111b of each medium flow channel 111 is connected to the reservoir tank 150 through a fourth circulation pipe 134.

Note that the plurality of flowrate regulating valves 180a to 180f may be collectively referred to as flowrate regulating valve 180. The first circulation pipe 131, the second circulation pipe 132, the third circulation pipe 133, and the fourth circulation pipe 134 may be collectively referred to as circulation pipe 130.

As described above, the cooler 100 is configured such that the cooling medium circulates in each medium flow channel 111 of the cooling member 110 through the circulation pipe 130. For example, in the cooler 100, when the pump 160 is operated, the cooling medium flows from the reservoir tank 150 into the cooling device 170 through the first circulation pipe 131 and the second circulation pipe 132 and is cooled by the cooling device 170. The cooling medium cooled by the cooling device 170 is supplied to each medium flow channel 111 of the cooling member 110 through the third circulation pipe 133. Then, the cooling medium circulating in and flowing out of each medium flow channel 111 is returned to the reservoir tank 150 through the fourth circulation pipe 134. Consequently, the cooling member 110 is cooled to a preset temperature, and accordingly, the panel substrate 10 fixedly adhered to the cooling member 110 and the LED elements 20 mounted on the panel substrate 10 are cooled to appropriate temperatures.

When the panel substrate 10 is cooled as described above, the operation of the cooler 100 is controlled by the controller 300 on the basis of detection results of the temperature sensors 200 provided on the panel substrate 10.

### <Temperature Detector>

As shown in FIG. 5, the temperature sensors 200 serving as the temperature detectors are provided on the panel substrate 10. More specifically, the temperature sensors 200 are provided in a plurality of measurement regions MA preset in the panel substrate 10, and detect the temperatures of the panel substrate 10 in the plurality of measurement regions MA.

At least one measurement region MA or more is preferably set in each adjustment region AA of the panel substrate 10. At least one of the plurality of temperature sensor 200 or more is preferably provided in each adjustment region AA of the panel substrate 10. Particularly, the plurality of temperature sensors 200 are preferably provided in each adjustment region AA.

However, the measurement region MA may not necessarily be set in each adjustment region AA. The measurement region MA may be set in, for example, a peripheral region of each adjustment region AA. That is, the temperature sensor 200 may not necessarily be provided in each adjustment region AA and may be provided in, for example, the peripheral region of each adjustment region AA.

As shown in FIG. 8, the display panel PNL1 of the display apparatus DSP1 according to one embodiment described here includes a plurality of pixels PIXa arranged in the matrix pattern on the surface of the panel substrate 10, and each pixel PIXa is includes a plurality of sub-pixels PIXS (PIXS1, PIXS2, and PIXS3). For example, each pixel PIXa includes a first sub-pixel PIXS1, a second sub-pixel PIXS2, and a third sub-pixel PIXS3. Note that the sub-pixel PIXS corresponds to each pixel PIX in the example of FIG. 1.

For example, the first sub-pixel PIXS1 includes an LED element 20 for emitting a visible light of red (R), the second sub-pixel PIXS2 includes an LED element 20 for emitting a visible light of green (G), and the third sub-pixel PIXS3 includes an LED element 20 for emitting a visible light of blue (B). The configuration of each pixel PIXa is merely one example, and is not limited to the configuration including the three sub-pixels PIXS1, PIXS2, and PIXS3. The number, density, arrangement, and the like of the sub-pixels PIXS of each pixel PIXa are not particularly limited, and may be different for each pixel PIXa.

In the present embodiment, the plurality of adjustment regions AA (AA1 to AA6) including the plurality of pixels PIXa are set in the panel substrate 10. The plurality of measurement regions MA are set to be correspond to the pixels PIXa, respectively. That is, the plurality of measurement regions MA are set in each adjustment region AA. Note that the size and the number of adjustment regions AA to be set in the panel substrate 10 are not particularly limited and may be appropriately determined.

The measurement region MA is set in a region where each pixel PIXa is provided, in proximity to the sub-pixels PIXS of each pixel PIXa. Each measurement region MA is arranged among the sub-pixels PIXS configuring each pixel PIXa. That is, each measurement region MA together with the sub-pixel PIXS is arranged in a matrix pattern on the panel substrate 10. The temperature sensor 200 is provided in the measurement region MA corresponding to each pixel PIXa. In this example, the temperature sensor 200 is provided in all the measurement regions MA set in the panel substrate 10. That is, the plurality of temperature sensors 200 corresponding to each pixel PIXa are provided in each adjustment region AA.

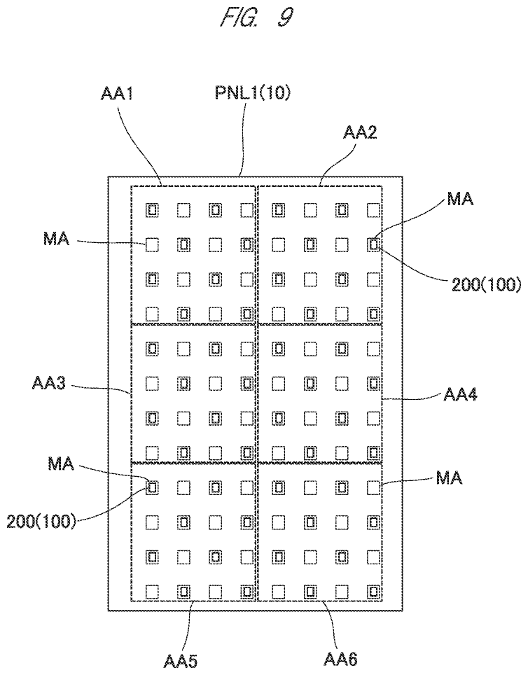

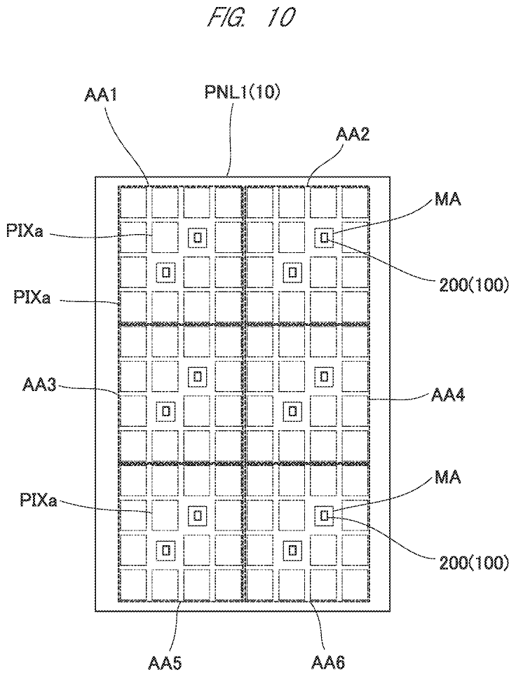

The temperature sensor 200 may not be necessarily provided in all the measurement regions MA. The temperature sensor 200 may be provided in some of the plurality of measurement regions MA set in the panel substrate 10. For example, as shown in FIG. 9, the temperature sensor 200 may be provided every other measurement region MA set in the matrix pattern in the panel substrate 10. Note that an interval between the temperature sensors 200 is not particularly limited, but may be substantially preferably constant. However, the interval between the temperature sensors 200 may not necessarily be constant. The temperature sensor 200 may be provided in a different region from the pixel PIXa. For example, as shown in FIG. 10, each temperature sensor 200 may be arranged between the pixels PIXa for each of the plurality of pixels PIXa.

For example, each of the plurality of temperature sensors 200 is made of a resistance temperature detector, a thermistor, a thermocouple, or the like formed by film formation on the surface of the panel substrate 10 and made of a metal such as platinum (Pt). Although not illustrated, on the panel substrate 10, a circuit wiring extending from each measurement region MA to the peripheral region PFA (see FIG. 1) is provided together with the wirings 31, 32 and the like for mounting the LED element 20. Each temperature sensor 200 is connected to the circuit wiring in each measurement region MA. Note that the circuit wiring is electrically isolated from the wirings 31, 32 and the like by an insulative layer. The circuit wiring is connected to the controller 300 through a connection wiring made of, for example, a flexible printed circuit (FPC) or the like. A detection result of each temperature sensor 200 is sent to the controller 300 through the circuit wiring and the connection wiring.

The temperature sensor 200 is not limited to the one formed by the film formation on the panel substrate 10. The temperature sensor 200 may be, for example, a temperature sensor element mounted on the circuit wiring provided in the panel substrate 10 in each measurement region MA. In this case, the circuit wiring may be provided in only a specific measurement region MA on which the temperature sensor element is mounted. However, the circuit wiring may be provided in all the measurement regions MA, and the temperature sensor element may be mounted on the specific measurement region MA.

### <Controller>

The controller 300 includes, for example, a field programmable gate array (FPGA) or the like to control the operation of the cooler 100 on the basis of the detection result of the temperature sensor 200 provided on the panel substrate 10. More specifically, the controller 300 controls the operation of the cooler 100 in accordance with the temperatures of the panel substrate 10 in the plurality of measurement regions MA in order to individually adjust the temperatures of the panel substrate 10 in the plurality of adjustment regions AA.

In other words, the controller 300 controls the operation of the cooler 100 on the basis of the temperatures of the panel substrate 10 in the measurement regions MA detected by the temperature sensors 200, and individually adjusts the temperatures of the plurality of adjustment regions AA set in the panel substrate 10. For example, the controller 300 individually adjusts the circulation state of the cooling medium circulating in each medium flow channel 111 of the cooling member 110, on the basis of the detection result of the temperature sensor 200. In other words, the controller 300 individually controls the operation of the cooling unit 120 of the cooler 100 such that the temperature of each adjustment region AA is the preset temperature in accordance with the temperature of the panel substrate 10 detected by the temperature sensor 200.

As described above, each cooling unit 120 includes the independent medium flow channel 111. Each cooling unit 120 includes the flowrate regulating valve 180. In this example, the configurations of the cooling units 120 are common except for the medium flow channel 111 and the flowrate regulating valve 180. Specifically, the reservoir tank 150, the pump 160, and the cooling device 170 in the cooler 100 are common among the cooling units 120. Of course, the reservoir tank 150, the pump 160, and the cooling device 170 may be provided for each cooling unit 120.

In the present embodiment, the controller 300 individually controls the operation of the flowrate regulating valve 180 configuring each cooling unit 120, on the basis of the detection results of the plurality of temperature sensors 200. That is, as the circulation state of the cooling medium, the controller 300 adjusts the flowrate of the cooling medium circulating in each medium flow channel 111. More specifically, the controller 300 individually controls the opening degree (degree of opening/closing states) of the flowrate regulating valve 180 configuring each cooling unit 120 such that the more cooling medium flows in the medium flow channel 111 of a high-temperature adjustment region among the plurality of adjustment regions AA of the panel substrate 10.

In this manner, the temperature of the panel substrate 10 in each adjustment region AA can be appropriately adjusted. For example, overcooling or insufficient cooling on each adjustment region AA of the panel substrate 10 can be suppressed to uniformize the entire temperature of the panel substrate 10.

As the circulation state of the cooling medium, note that the controller 300 may adjust, for example, the cooling temperature of the cooling medium. Specifically, the controller 300 may control the operation of the cooling device 170 on the basis of the detection result of the temperature sensor 200 to adjust the cooling temperature of the cooling medium supplied to each medium flow channel 111. Since the cooling temperature of the cooling medium is adjusted in addition to the flowrate of the cooling medium supplied to each medium flow channel 111, the temperature of the panel substrate 10 in each adjustment region AA can be appropriately adjusted.

### Example of Method of Adjusting Temperature

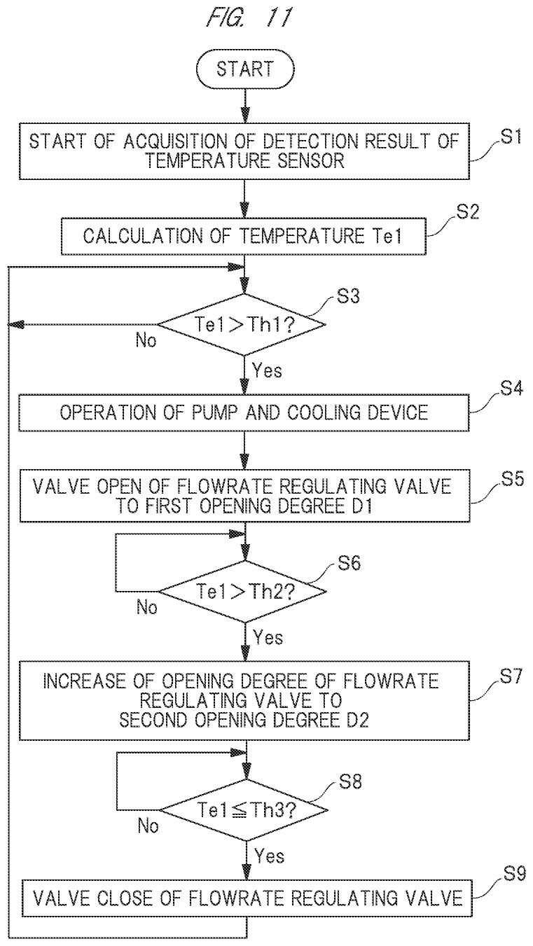

An example of a method of adjusting the temperature of the display apparatus, that is an example of the control for the operation of the cooler 100 under the controller 300, will be explained below. FIG. 11 is a flowchart showing the example of the method of adjusting the temperature of the display apparatus.

The method of adjusting the temperature for one adjustment region AA1 of the panel substrate 10 will be basically explained below. However, practically, the same temperature adjustment is individually performed on the plurality of adjustment regions AA. For example, in the configuration of FIG. 5, the same temperature adjustment is individually performed on the plurality of adjustment regions AA1 to AA6.

By activation of the display apparatus DSP1, the control for the operation of the cooler 100 under the controller 300 is started. First, a first step of detecting the temperatures of the panel substrate 10 in the measurement regions MA set in the panel substrate 10 is performed.

For example, as shown in FIG. 11, in step S1, acquisition of the detection results of the plurality of temperature sensors 200 provided in the adjustment region AA1 of the panel substrate 10 starts. That is, acquisition of the temperature of each measurement region MA of the adjustment region AA1 starts. Next, on the basis of the detection results of the plurality of temperature sensors 200, a temperature Tel of the adjustment region AA1 is calculated (step S2).

For example, the mean value of the detection results of the plurality of temperature sensors 200 is calculated as the temperature Tel of the adjustment region AA1. Note that a method of calculating the temperature Tel of the adjustment region AA1 is not limited to this example. For example, the maximum value of the detection results of the temperature sensors 200 may be calculated as the temperature Tel of the adjustment region AA1. In this example, it is assumed that the detection results of the temperature sensors 200 are acquired at predetermined time intervals after the start of the acquisition of the detection results of the temperature sensors 200. Further, it is assumed that the temperature Tel of the adjustment region AA1 is calculated on the basis of the acquired detection results and is sequentially updated.

Next, a second step of individually adjusting the temperatures of the plurality of adjustment regions AA set in the panel substrate 10 are performed in accordance with the temperatures of the panel substrate 10 detected in the plurality of measurement regions MA.

For example, first, it is determined whether the temperature Tel of the adjustment region AA1 is higher than a preset first threshold Th1 (step S3). Then, if it is determined that the temperature Tel of the adjustment region AA1 is higher than the first threshold Th1 (step S3: Yes), the processing proceeds to step S4. In step S4, the pump 160 and the cooling device 170 in the cooler 100 are operated. Further, in step S5, the flowrate regulating valve 180a corresponding to the adjustment region AA1 is opened to preset first opening degree D1.

Next, it is determined whether the temperature Tel of the adjustment region AA1 is higher than a preset second threshold Th2 (step S6). The second threshold Th2 is set to be higher than the first threshold Th1. If it is determined that the temperature Tel of the adjustment region AA1 is higher than the second threshold Th2 (step S6: Yes), the processing proceeds to step S7.

In step S7, the circulation state of the cooling medium of the medium flow channel 111 corresponding to the adjustment region AA1 is adjusted. Specifically, the flowrate of the cooling medium circulating in the medium flow channel 111 corresponding to the adjustment region AA1 is increased. For example, the opening degree of the flowrate regulating valve 180a is increased to preset second opening degree D2. The second opening degree D2 is set larger than the first opening degree D1 and equal to or smaller than the maximum opening degree of the flowrate regulating valves 180.

When the circulation state of the cooling medium is adjusted in step S7, the opening degree of the flowrate regulating valve 180a may be increased, and the output of the pump 160 may be increased. At this time, if only the flowrate regulating valve 180a corresponding to the adjustment region AA1 is opened, the opening degree of the flowrate regulating valve 180a may be kept while the output of the pump 160 may be increased.

Next, it is determined whether the temperature Tel of the adjustment region AA1 is equal to or lower than a preset third threshold Th3 (step S8). The third threshold Th3 is set to be lower than, for example, the first threshold Th1. Then, if it is determined that the temperature Tel of the adjustment region AA1 is equal to or lower than the third threshold Th3 (step S8: Yes), the processing proceeds to step S9. In step S9, the circulation state of the cooling medium of the medium flow channel 111 corresponding to the adjustment region AA1 is adjusted. For example, the flowrate regulating valve 180a corresponding to the adjustment region AA1 is closed. The operations of the cooling device 170 and the pump 160 are stopped as needed.

Then, the processing returns to step S3. Then, if it is determined that the temperature Tel of the adjustment region AA1 is equal to or higher than the first threshold Th1 or higher again (step S3: Yes), the processing proceeds to step S4, and the control for the flowrate regulating valve 180a of the cooler 100 and the like restarts.

As described above, in the display apparatus DSP1 according to one embodiment, when the temperature of the display panel PNL1 is adjusted, the temperature of the panel substrate 10 is detected in the plurality of measurement regions MA set in the panel substrate 10. Then, the temperature of each adjustment region AA is individually adjusted (for example, cooled) in accordance with the temperature of the panel substrate 10 detected in the plurality of measurement regions MA.

In other words, the controller 300 is configured to control the cooler 100 on the basis of the detection results of the plurality of temperature sensors 200 provided in the panel substrate 10, and to individually adjust the temperatures of the panel substrate 10 in the plurality of adjustment regions AA. That is, the controller 300 is configured to individually adjust each cooling unit 120 of the cooler 100.

In this manner, the temperature of the panel substrate 10 on which the plurality of LED elements 20 are mounted can be more appropriately adjusted. For example, in the adjustment region AA in which the temperature of the panel substrate 10 is relatively high due to heat produced by the LED elements 20, the flowrate of the cooling medium is increased to enable the panel substrate 10 to be actively cooled. To the contrary, in the adjustment region AA in which the temperature of the panel substrate 10 is relatively low, the flowrate of the cooling medium is decreased to enable the panel substrate 10 to be suppressed from being cooled. Thus, the overcooling or the insufficient cooling of each adjustment region AA of the panel substrate 10 can be suppressed to enable the entire panel substrate 10 to be appropriately cooled.

Since the temperature sensors 200 are provided on the panel substrate 10, the temperature of the panel substrate 10 in each measurement region MA can be detected in real time. Thus, since the cooler 100 is controlled on the basis of the detection results of the plurality of temperature sensors 200, the temperature of the panel substrate 10 in each adjustment region AA can be more appropriately adjusted.

### Modification Example

In the foregoing, one embodiment of the present invention has been explained. However, the present invention is not limited to the foregoing embodiment. The present invention can be variously modified within the scope of the present invention. Further, another structure can be added to/eliminated from/replaced with a part of the structure of the embodiment.

For example, in the above-described embodiment, the example in which the circulation state of the cooling medium circulating in the medium flow channel 111 is adjusted at two stages as the method of adjusting the temperature of the display apparatus DSP1 has been explained. However, the circulation state of the cooling medium may be adjusted at, for example, three or more stages. In the above-described example, the case in which the opening degree of the flowrate regulating valve 180 is controlled at two stages has been explained. However, the opening degree of the flowrate regulating valve 180 may be controlled at three or more stages. Further, the flowrate regulating value 180 may be, for example, an ON-OFF valve that switches the ON state and the OFF state. Even in this case, for example, by control for time of the opening of the flowrate regulating valve 180 or the like, the temperature of the panel substrate 10 in each adjustment region AA is individually adjusted.

As described above, the medium flow channels 111 provided in the cooling member 110 preferably correspond to the plurality of adjustment regions AA, respectively, but may not necessarily correspond to the adjustment regions AA, respectively. For example, in the cooing member 110, the plurality of medium flow channels 111 are provided to correspond to the plurality of adjustment regions AA, respectively. For example, if six adjustment regions AA are set in the panel substrate 10, three medium flow channels 111 each corresponding to two adjustment regions AA may be provided in the cooling member 110.

Further, so-called water-cooling type apparatus in which the cooling member is cooled by the cooling medium has been exemplified as the cooler 100 serving as the temperature adjuster. However, the cooler 100 is limited to the water-cooling type apparatus. For example, the cooler 100 may be an air-cooling type apparatus. Further, in the above-described example, the cooler has been explained as the temperature adjuster. However, the temperature adjuster is not necessarily limited to the cooler. The temperature adjuster may be any apparatus capable of adjusting the temperature of the panel substrate 10, such as an apparatus have a heating function.

As one embodiment, the example in which the temperature of the panel substrate 10 is detected by the temperature sensor 200 formed on the panel substrate 10 by the film formation or the like has been explained. However, the method of detecting the temperature of the panel substrate 10 is not limited to this example. The temperature of the panel substate 10 may be detected by, for example, a non-contact temperature sensor at a position away from the panel substrate 10.

### <Statements>

### (Statement 1)

In a method of adjusting a temperature of an electronic apparatus including a panel substrate on which a plurality of elements are mounted, the method includes: a first step of detecting temperatures of the panel substrate in a plurality of measurement regions set in the panel substrate; and a second step of individually adjusting temperatures of a plurality of adjustment regions set in the panel substrate in accordance with the detected temperatures of the panel substrate in the plurality of measurement regions.

### (Statement 2)

In the method of adjusting the temperature of the electronic apparatus described in the statement 1, each of the plurality of adjustment regions of the panel substrate is provided with at least one of the plurality of measurement regions, and, in the first step, temperatures of the panel substrate are detected in the plurality of measurement regions provided in the plurality of adjustment regions of the panel substrate, respectively.

### (Statement 3)

In the method of adjusting the temperature of the electronic apparatus described in the statement 1 or 2, the electronic apparatus includes a cooler having a cooling member connected to the panel substrate and configured to cool the panel substrate, the cooling member includes a plurality of medium flow channels corresponding to the plurality of adjustment regions of the panel substrate and configured to circulate a cooling medium therein, and, in the second step, circulation states of the cooling medium circulating in the plurality of medium flow channels are individually adjusted in accordance with the temperatures of the panel substrate in the plurality of measurement regions, respectively.

### (Statement 4)

In the method of adjusting the temperature of the electronic apparatus described in the statement 3, in the second step, flowrates of the cooling medium circulating in the plurality of medium flow channels are individually adjusted as the circulation states of the cooling medium.

### (Statement 5)

In the method of adjusting the temperature of the electronic apparatus described in the statement 4, in the second step, cooling temperatures of the cooling medium circulating in the plurality of medium flow channels are further adjusted as the circulation states of the cooling medium.

### (Statement 6)

In an electronic apparatus including a panel substrate on which a plurality of elements are mounted, the electronic apparatus includes: a plurality of temperature detectors provided in a plurality of measurement regions set in the panel substrate and configured to detect temperatures of the panel substrate; a temperature adjuster including a plurality of temperature adjusting units corresponding to a plurality of adjustment regions set in the panel substrate, and configured to adjust the temperatures of the panel substrate; and a controller configured to control an operation of the temperature adjuster, and the controller individually controls operations of the plurality of temperature adjusting units in accordance with the temperatures of the panel substrate in the plurality of measurement regions detected by the plurality of temperature detectors.

### (Statement 7)

In the electronic apparatus described in the statement 6, each of the plurality of adjustment regions of the panel substrate is provided with at least one of the plurality of temperature detectors.

### (Statement 8)

In the electronic apparatus described in the statement 6 or 7, the temperature adjuster includes a cooling member connected to the panel substrate and including a plurality of medium flow channels configured to circulate a cooling medium therein, the plurality of temperature adjusting units independently include the plurality of medium flow channels, respectively, and the controller individually adjusts circulation states of the cooling medium circulating in the plurality of medium flow channels in accordance with temperatures of the panel substrate in the plurality of measurement regions detected by the plurality of temperature detectors.

### (Statement 9)

In the electronic apparatus described in the statement 8, the controller individually adjusts flowrates of the cooling medium circulating in the plurality of medium flow channels as circulation states of the cooling medium.

### (Statement 10)

In the electronic apparatus described in the statement 9, the controller further adjusts cooling temperatures of the cooling medium circulating in the plurality of medium flow channels as the circulation states of the cooling medium.

### (Statement 11)

In the electronic apparatus described in any one of the statements 6 to 10, each of the plurality of temperature detectors is a thermistor, a resistance temperature detector, or a thermocouple formed by film formation on a surface of the panel substrate.

### (Statement 12)

In the electronic apparatus described in any one of the statements 6 to 10, each of the plurality of temperature detectors is a temperature sensor element mounted on a wiring formed on the panel substrate.

The present invention is applicable to a method of adjusting a temperature of an electronic apparatus including a substrate on which an electronic component (element) is mounted, and to an electronic apparatus.

What is claimed is:

1. A method of adjusting a temperature of an electronic apparatus including a panel substrate on which a plurality of elements are mounted, comprising:
a first step of detecting temperatures of the panel substrate in a plurality of measurement regions set in the panel substrate; and
a second step of individually adjusting temperatures of a plurality of adjustment regions set in the panel substrate in accordance with the detected temperatures of the panel substrate in the plurality of measurement regions.

2. The method of adjusting the temperature of the electronic apparatus according to claim 1,
each of the plurality of adjustment regions of the panel substrate is provided with at least one of the plurality of measurement regions, and,
in the first step, the temperatures of the panel substrate are detected in the plurality of measurement regions provided in the plurality of adjustment regions of the panel substrate, respectively.

3. The method of adjusting the temperature of the electronic apparatus according to claim 1,
wherein the electronic apparatus includes a cooler having a cooling member connected to the panel substrate and configured to cool the panel substrate,
the cooling member includes a plurality of medium flow channels corresponding to the plurality of adjustment regions of the panel substrate and configured to circulate a cooling medium therein, and,
in the second step, circulation states of the cooling medium circulating in the plurality of medium flow channels are individually adjusted in accordance with the temperatures of the panel substrate in the plurality of measurement regions.

4. The method of adjusting the temperature of the electronic apparatus according to claim 2,
wherein the electronic apparatus includes a cooler having a cooling member connected to the panel substrate and configured to cool the panel substrate,
the cooling member includes a plurality of medium flow channels corresponding to the plurality of adjustment regions of the panel substrate and configured to circulate a cooling medium therein, and,
in the second step, circulation states of the cooling medium circulating in the plurality of medium flow channels are individually adjusted in accordance with the temperatures of the panel substrate in the plurality of measurement regions.

5. The method of adjusting the temperature of the electronic apparatus according to claim 3,
wherein, in the second step, flowrates of the cooling medium circulating in the plurality of medium flow channels are individually adjusted as the circulation states of the cooling medium.

6. The method of adjusting the temperature of the electronic apparatus according to claim 4,
wherein, in the second step, flowrates of the cooling medium circulating in the plurality of medium flow channels are individually adjusted as the circulation states of the cooling medium.

7. The method of adjusting the temperature of the electronic apparatus according to claim 5,
wherein, in the second step, cooling temperatures of the cooling medium circulating in the plurality of medium flow channels are further adjusted as the circulation states of the cooling medium.

8. The method of adjusting the temperature of the electronic apparatus according to claim 6,
wherein, in the second step, cooling temperatures of the cooling medium circulating in the plurality of medium flow channels are further adjusted as the circulation states of the cooling medium.

9. An electronic apparatus including a panel substrate on which a plurality of elements are mounted, comprising:
a plurality of temperature detectors provided in a plurality of measurement regions set in the panel substrate and configured to detect temperatures of the panel substrate;
a temperature adjuster including a plurality of temperature adjusting units corresponding to a plurality of adjustment regions set in the panel substrate, and configured to adjust the temperatures of the panel substrate; and
a controller configured to control an operation of the temperature adjuster,
wherein the controller individually controls operations of the plurality of temperature adjusting units in accordance with temperatures of the panel substrate in the plurality of measurement regions detected by the plurality of temperature detectors.
